(19) United States
(12) Patent Application Publication
(10) Pub. No.: US 2008/0158449 A1
(43) Pub. Date: Jul. 3, 2008

(54) ELECTRIC FIELD REDUCTION IN DISPLAY DEVICE

(75) Inventors: DODGE D. DAVERMAN, CHICAGO, IL (US); ROBERT D. POLAK, LINDENHURST, IL (US); CHRISTOPHER J. SPIEK, EAST DUNDEE, IL (US)

Correspondence Address: MOTOROLA INC, 600 NORTH US HIGHWAY 45, W4 - 39Q, LIBERTYVILLE, IL, 60048-5343, US

(73) Assignee: MOTOROLA, INC., LIBERTYVILLE, IL (US)

(21) Appl. No.: 11/617,097

(22) Filed: Dec. 28, 2006

(51) Int. Cl. G02F 1/133; H01L 21/02

(52) U.S. Cl. 349/33; 438/30; 257/E21.001

(57) ABSTRACT

A method includes forming a first electrode on a first substrate and forming a second electrode on a second substrate. A layer of liquid crystal material is positioned between the first electrode and the second electrode. A voltage V(e) is applied between the first electrode and the second electrode to produce an electric field. A layer of dielectric material is provided that has at least one area defined by a void. The layer of dielectric material is utilized to block the electric field other than in the area defined by the void.

### FIELD

The present application relates to display devices, and more particularly to liquid crystal display devices.

### BACKGROUND

The instability of plastic substrates makes registering front and rear electrodes difficult in a roll to roll process. Yet, roll to roll processes are seen as more efficient than batch processes. Accordingly, manufacturers developed processes in which a first electrode is non-patterned and a second electrode is patterned. However, such a construction can result in the presence of unwanted electric fields between the traces on the patterned electrode and the non-patterned electrode that cause unintended shuttering. Therefore, what is needed is either a roll-to-roll process that is capable of accurately registering the front and rear substrates, or a display construction that eliminates or sufficiently reduces the electric field between the traces of the patterned electrode and the non-patterned electrode.

### BRIEF DESCRIPTION OF THE DRAWINGS

For the purpose of facilitating an understanding of the subject matter sought to be protected, there are illustrative embodiments in the accompanying drawing, from an inspection of which, when considered in connection with the following description and claims, the subject matter sought to be protected, its construction and operation, and many of its advantages should be readily understood and appreciated

FIG. 1A depicts two patterned electrodes that are registered.

FIG. 1B depicts a patterned electrode and a non-patterned electrode.

FIG. 2 depicts one example of a process by which a layer of dielectric material is added and positioned between a first electrode and a second electrode to block unwanted electric fields.

FIG. 3 depicts one example of an exploded cross sectional view of a liquid crystal display formed from the process shown in FIG. 2.

FIG. 4 depicts a voltage versus transmission curve for one example of a liquid crystal display formed from the process of FIG. 2.

### DETAILED DESCRIPTION

In one example a method is provided. A first electrode is formed on a first substrate. A second electrode is formed on a second substrate. A layer of optically active material is positioned between the first electrode and the second electrode. A voltage V(e) is applied between the first electrode and the second electrode to produce an electric field. A layer of dielectric material having at least one area defined by a void is provided. The layer of dielectric material is utilized to reduce the electric field across the optically active material other than in the area defined by the void.

In another example, a method of operating a display is provided. The display comprises a first electrode on a first substrate, a second electrode on a second substrate, and a layer of liquid crystal emulsified material between the first substrate and the second substrate. A voltage V(e) is applied between the first electrode and the second electrode to create an electric field that runs through the layer of liquid crystal emulsified material. At least a portion of the electric field is blocked, through utilization of a dielectric material positioned over the first electrode, to create at least one non-visible area in the display.

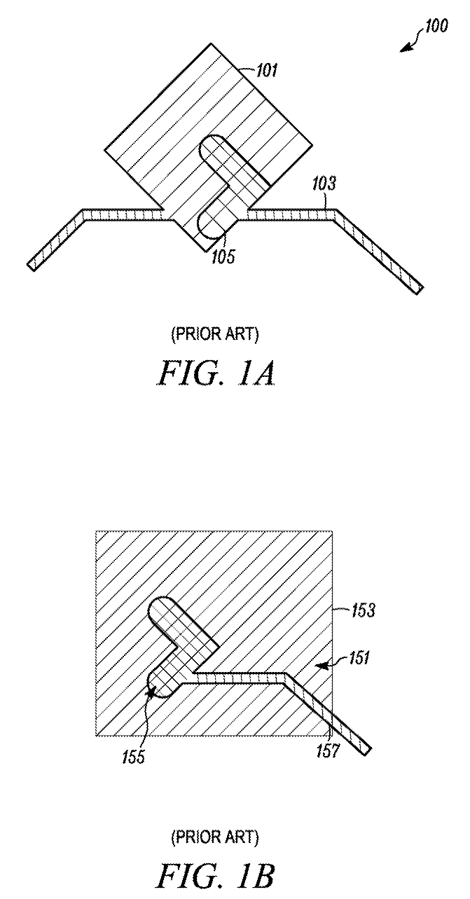

Referring to FIG. 1A, in one example, a display construction 100 is shown in which a first patterned electrode 101 is shown registered with a second patterned electrode 103. The first patterned electrode 101 and the second patterned electrode 103 meet in an overlapping area 105. A layer of optically active material, such as liquid crystal material (not shown) is positioned between the first electrode and the second electrode. When a signal is applied to each electrode, an electric field is set up across the optically active material in the area defined by the intersection of the two electrodes. The optically active material that is exposed to this electric field reacts in such a way as to increase the transmitted light.

Registering first electrode 101 and second electrode 103 is difficult in a roll-to-roll process. Consequently, manufacturers developed another construction 150 shown in FIG. 1B. A first electrode 151 and a second electrode 153 intersect in an overlapping area 155. First electrode 151 is patterned and second electrode 153 is un-patterned.

By “patterned” it is mean that the electrode itself has geometry. In one example, a patterned electrode is formed by coating a substrate made of a first material, such polyethylene terephthalate, with a layer of material, such as Indium Tin Oxide (ITO) (e.g. through sputtering) and applying a photo resist to it. Portions of this layer are then etched away thereby creating a specific geometry. An un-patterned electrode covers the entire substrate onto which it has been coated or sputtered.

By keeping second electrode 153 un-patterned, registration is no longer required because there is no pattern on the second electrode 153 (i.e. there are no two patterns that need registration). An unwanted by-product of this approach, however, is that the patterned electrode's traces 157 will always overlap with the second unpatterned electrode, thereby creating an electric field in an area where it is not desired to have one.

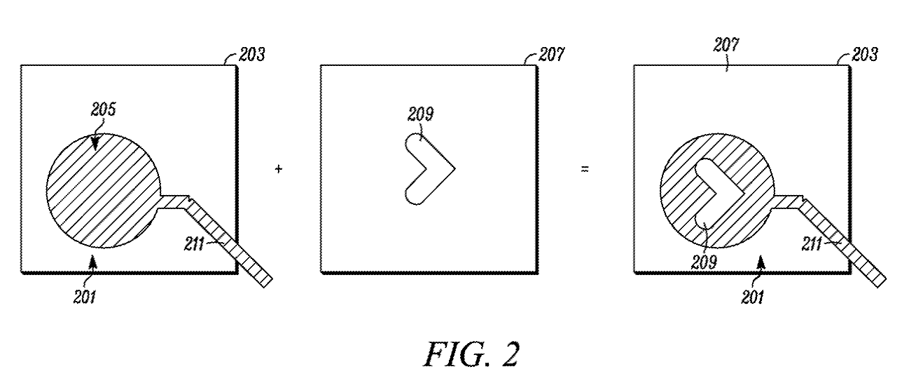

The construction shown in FIG. 2 reduces the level of unwanted electric fields between traces and un-patterned electrodes. A first electrode 201 and a second electrode 203 again will overlap to create an illumination area 205. A mask of dielectric material 207 is added between the first electrode 201 and the second electrode 203. A void 209 is created in the dielectric material. The dielectric material reduces the electric field applied to the liquid crystal between the first electrode 201 and 203. Accordingly, only the area defined by the void 209 will allow the full electric field between the two electrodes to be applied across the liquid crystal. As a result, only the area defined by this void is illuminated when an electric field is applied between the first electrode 201 and the second electrode 203. Therefore, unwanted electric fields do not occur between the trace 211 and the un-patterned electrode 203.

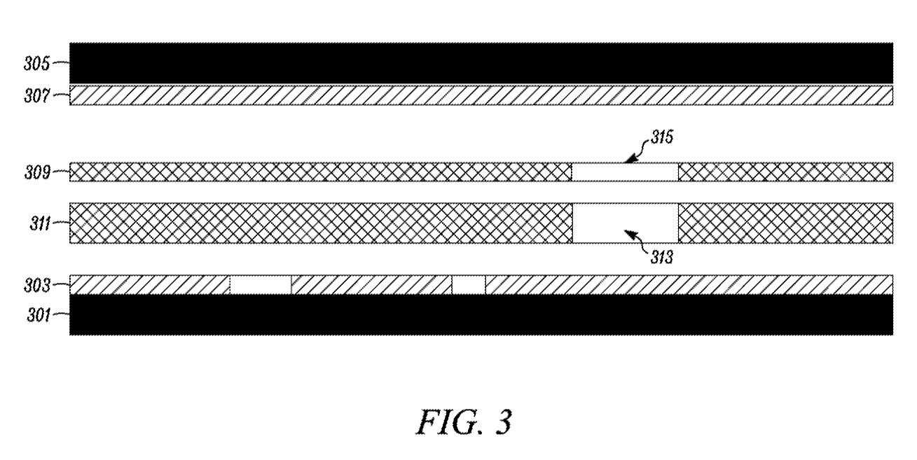

Referring to FIG. 3, an exploded cross sectional view of display device 300 is shown for illustrative purposes.

Display device in one example comprises a first substrate 301 and a first electrode 303 formed on the first substrate. A second substrate 305 and a second electrode 307 formed on the second substrate. A layer of optically active material 309 is positioned between the first substrate 301 and the second substrate 303. In one example, the optically active material is liquid crystal material. It should be noted, however, that the optically active material can comprise any material that either transmits, emits or reflects light based on applied voltage. A layer of dielectric material 311 is formed over the first electrode 303. The dielectric material layer 311 includes a void 313.

Referring further to FIG. 3, first substrate 301 and second substrate 305 are made of a plastic, such as polyethylene terephthalate. In another example, the substrates 301, 305 are made of another material, such as glass, PEN film, polycarbonate film, and the like. Electrodes 303, 307 in one example are formed from indium tin oxide. In another example, electrodes 303, 307 are formed from another material, such as Orgacon, PEDOT, screen printable conductors, silver or aluminum. The layer of liquid crystal material 309 in one example is a liquid crystal emulsion, such as an nematic curvilinear aligned phase (NCAP) emulsion. Alternatively, liquid crystal layer 309 could comprise another material, such as polymeric dispersed liquid crystal, twisted Nematic Liquid Crystal (TN), Super Twisted Nematic Liquid Crystal (STN), electronically controlled birefringence liquid crystal, in-plane switching liquid crystal, electrochromic material, electrophoretic material, organic light emitting diodes, cholesteric Liquid Crystal (ChLC), electrowetting display, or any display technology that operates by the optical properties of the material changing in reaction to an applied electric field.

Dielectric material layer 311 in one example is a clear dielectric material, such as titanium oxide that is formed over first electrode 303. In one example, dielectric layer 311 is formed over first electrode 303 by utilizing it is a dielectric ink and printing it over first electrode 303 with a method, such as screen printing, pad printing, vapor deposition, or with an ink-jet printer. In one example, dielectric layer 311 has a thickness that is less than or equal to the liquid crystal layer 309. For example, the thickness of the dielectric material may be a few microns. Void 313 in dielectric material 311 defines an area of illumination 315 when an electric field is applied to first electrode 303 and second electrode 307 and light is incident on the optically active material layer 309.

Finally, it should be noted that the dielectric layer in between the two display substrates can be modeled as a capacitor in series with a capacitor that represents the optically active material. To reduce the electric field (or voltage) across the optically active material, the capacitance of the dielectric layer needs to be much smaller than the capacitance of the optically active material. The voltage drop (V1) across a capacitor (C1) in series with a capacitor (C2) is given by the equation V2=C1/(C1+C2). The smaller capacitor sees the larger voltage drop. To make the capacitance of the dielectric layer smaller than the capacitance of the optically active, the designer will need to consider the ratios of the two materials permittivity as well as the ratios of the thicknesses of the two materials. The lower the permittivity and the thicker the dielectric layer, the lower will be the capacitance. However, a thicker dielectric layer could potentially introduce optical problems. Accordingly, the thickness of the material must be balanced against the optical properties that are desired.

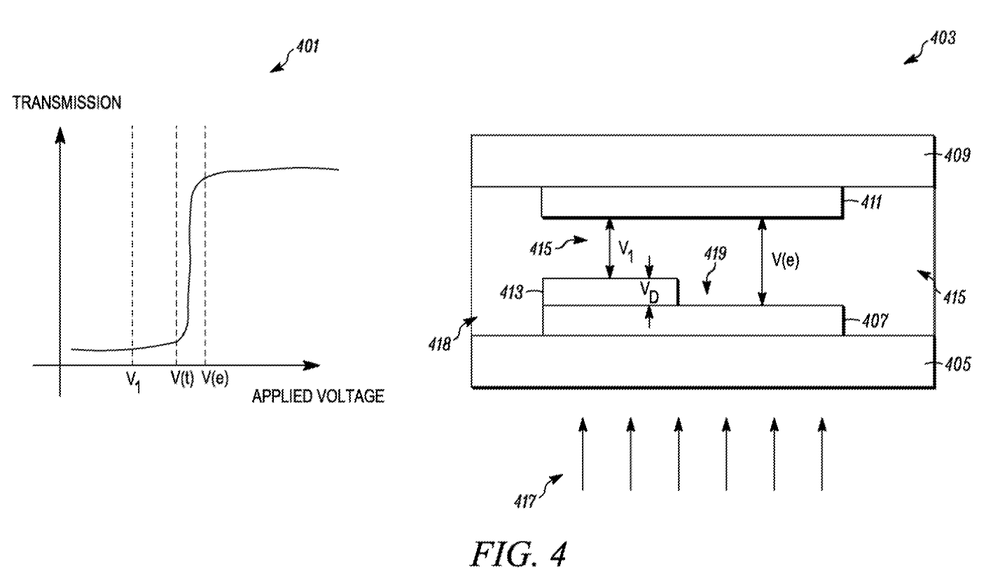

Referring to FIG. 4, a transmission versus voltage curve 401 is shown for display device 403. Display device 403 includes a first substrate 405 with a first electrode 407 formed thereon; a second substrate 409 with a second electrode 411 formed thereon. A layer of dielectric material 413 is formed over the first electrode 407. And a optically active material layer 415 is formed on the first substrate 405. In one example, optically active material layer is a twisted nematic (TN), super twisted nematic (STN), or Ferroelectric and nematic liquid crystal display (FNLCD). Each of these liquid crystal layers have a threshold voltage V(t). When a voltage is applied to the liquid crystal layer 415 it will transmit light 417 if the applied voltage is above V(t). The liquid crystal layer 415 will not transmit light if the applied voltage is below V(t).

Referring further to FIG. 4, when a voltage V(e) is applied to the electrodes 407, 411, the liquid crystal material 415 will receive that voltage except in the area where dielectric layer 413 is present. In this area, there is a voltage drop V(d) across the dielectric layer. Consequently, liquid crystal material layer 415 receives a voltage V(1) equal to V(e) minus V(d) in these areas. Provided V(1) remains less than V(t) and V(e) remains greater than V(t), then the dielectric will divide the voltage V(e) such that the area with the dielectric coating will appear exactly the same as a region 418 where no voltage is present. Accordingly, there will be a well defined boundary between the areas with dielectric material 413 and the areas defined by voids 419.

While particular embodiments have been shown and described, it will be apparent to those skilled in the art that changes and modifications may be made without departing from the principles set forth herein. The matter set forth in the foregoing description and accompanying drawings is offered by way of illustration only and not as a limitation.

1. A method, comprising:
forming a first electrode on a first substrate;
forming a second electrode on a second substrate;
positioning a layer of optically active material crystal material between the first electrode and the second electrode;
applying a voltage V(e) between the first electrode and the second electrode to produce an electric field;
providing a layer of dielectric material having at least one area defined by a void; and
utilizing the layer of dielectric material to reduce the electric field other than in the area defined by the void.

2. The method of claim 1, wherein the step of forming the first electrode comprises:
forming a patterned electrode on the first substrate.

3. The method of claim 2, wherein the step of forming the second electrode comprises:
forming a non-patterned electrode on the second substrate

4. The method of claim 2, further comprising:
printing the dielectric material over the patterned electrode.

5. The method of claim 4, wherein the step of printing comprises:
printing a titanium oxide layer over the patterned electrode.

6. The method of claim 1, wherein the step of applying the voltage comprises:
producing an electric field to create an area of illumination defined by the void.

7. The method of claim 1, further comprising:
selecting the optically active material such that it operates in a first mode when an applied voltage V(a) is below a threshold voltage V(t) and operates in a second mode when V(a) is above a threshold voltage V(t).

8. The method of claim 7, wherein the step of providing the dielectric material such that when the V(e) is applied, a voltage drop V(d) occurs across the dielectric material.

9. The method of claim 8, wherein the step of providing the dielectric material comprises:
selecting the dielectric material such that V(t) is greater than V(e) minus V(d).

10. The method of claim 1, wherein the step of providing the layer of dielectric material comprises:
providing the layer of dielectric material such that it has a thickness that is less than or equal to a thickness of the layer of liquid crystal material.

11. The method of claim 1, further comprising:
selecting the optically active material to be a liquid crystal material.

12. A method of operating a display comprising a first electrode on a first substrate, a second electrode on a second substrate, and a layer of optically active material between the first substrate and the second substrate, the method comprising:
applying a voltage V(e) between the first electrode and the second electrode to create an electric field that runs through the layer of optically active material; and
reducing at least a portion of the electric field, through utilization of a dielectric material positioned over the first electrode, to create at least one non-visible area in the display.

13. The method of claim 12, wherein the step of blocking comprises:
positioning a layer of dielectric material, having at least one void, over the first electrode, wherein the at least one void defines at least one visible area in the display.

14. The method of claim 13, wherein the step of positioning comprises:
printing the layer of dielectric material over the first electrode prior to applying the voltage.

15. The method of claim 12, further comprising:
selecting the dielectric material such that a voltage drop V(d) occurs across the dielectric material when V(e) is applied to the first electrode and the second electrode.

16. The method of claim 15, wherein the step of selecting the dielectric material comprises:
selecting the dielectric material such that V(e)−V(d) is less than a threshold voltage of the optically active material.

17. The method of claim 16, wherein the step of selecting the dielectric material comprises:
selecting titanium oxide as the dielectric material.

18. The method of claim 17, wherein the step of selecting the dielectric material comprises:
selecting the dielectric material to have a thickness that is less than or equal to a thickness of the optically active material.

19. The method of claim 12, wherein the optically active material is a liquid crystal emulsified material.
